(19) United States
(12) Patent Application Publication
(10) Pub. No.: US 2010/0096004 A1
(43) Pub. Date: Apr. 22, 2010

(54) SOLAR CELL WITH NANOSTRUCTURE ELECTRODE(S)

(75) Inventors: Liangbing Hu, Los Angeles, CA (US); David Hecht, Santa Monica, CA (US); George Gruner, Los Angeles, CA (US)

Correspondence Address: UNIDYM Inc., 1244 Reamwood Avenue, Sunnyvale, CA, 94089, US

(73) Assignee: UNIDYM, INC., Pasadena, CA (US)

(21) Appl. No.: 11/552,638

(22) Filed: Oct. 25, 2006

(51) Int. Cl. H01L 31/00; H01L 33/00; H01L 51/42; H01L 51/50

(52) U.S. Cl. 136/256; 438/24; 257/40; 977/932; 257/E51.026; 257/E33.076

(57) ABSTRACT

A solar cell comprising at least one nanostructure-film electrode is discussed. The solar cell may further comprise a different conducting material, such as a conducting polymer, to fill pores in the nanostructure-film. Additionally or alternatively, the solar cell may comprise an electrode grid superimposed on the nanostructure-film. Likewise, the solar cell may have a single or multiple active layer(s), wherein nanostructure-film(s) may form at least semi-transparent anode(s) and/or cathode(s) through use of buffer layer(s).

### COPYRIGHT & TRADEMARK NOTICE

A portion of the disclosure of this patent document contains material that is subject to copyright protection. The owner has no objection to the facsimile reproduction by any one of the patent document or the patent disclosure, as it appears in the Patent and Trademark Office patent file or records, but otherwise reserves all copyrights whatsoever.

Certain marks referenced herein may be common law or registered trademarks of third parties affiliated or unaffiliated with the applicant or the assignee. Use of these marks is by way of example and shall not be construed as descriptive or limit the scope of this invention to material associated only with such marks.

### FIELD OF THE INVENTION

The present invention relates in general to solar cells, and more particularly to thin-film solar cells comprising at least one nanostructure-film.

### BACKGROUND OF THE INVENTION

A solar cell is a photoelectric device that converts photons from the sun (solar light) into electricity. Fundamentally, the device needs to photo-generate charge carriers (e.g., electrons and holes) in a photosensitive active layer, and separate the charge carriers to a conductive electrode that will transmit the electricity.

Historically, bulk technologies employing crystalline silicon (c-Si) have been used as the light-absorbing semiconductors in most solar cells, despite the fact that c-Si is a poor absorber of light and requires a high material thickness (e.g., hundreds of microns). However, the high cost of c-Si wafers has led the industry to research alternate, and generally less-expensive, solar cell materials.

Specifically, thin film solar cells can be created with relatively inexpensive materials on flexible surfaces. The selected materials are preferably strong light absorbers and need only be about a micron thick, thereby reducing materials costs significantly. Such materials include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

Regardless of the thin-film device architecture chosen, an at least semi-transparent conducting layer is required to form a front electrical contact of the cell, so as to allow light transmission through to the active layer(s). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

Currently, the most commonly used transparent electrodes are transparent conducting oxides (TCOs), specifically indium-tin-oxide (ITO) on glass. However, ITO can be an inadequate solution for many emerging applications (e.g., non-rigid solar cells due to ITO's brittle nature), and the indium component of ITO is rapidly becoming a scarce commodity. Moreover, deposition of transparent conducting oxides (TCOs) for minimal light loss normally requires a sputtering process, which can severely damage underlying active layers.

Consequently, more robust and abundant transparent conductors are required not only for solar cell applications but for optoelectronic applications in general.

### SUMMARY OF THE INVENTION

The present invention provides an optoelectronic device comprising at least one nanostructure-film.

Nanostructure-films include, but are not limited to, network(s) of nanotubes, nanowires, nanoparticles and/or graphene flakes. Specifically, transparent conducting nanostructure-films composed of randomly distributed SWNTs (networks) have been demonstrated as substantially more mechanically robust than ITO. Additionally, SWNTs can be deposited using a variety of low-impact methods (e.g., it can be solution processed), and comprise carbon, which is one of the most abundant elements on Earth. Nanostructure-films according to embodiments of the present invention were demonstrated as having sheet resistances of less than 300 Ω/square with at least 90% optical transmission of 550 nm light.

A solar cell according to an embodiment of the present invention comprises a photosensitive active layer sandwiched between a first electrode and a second electrode, wherein at least one of the first and second electrodes comprises a network of nanostructures (e.g., a nanostructure-film). Active layers compatible with the present invention may include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

A solar cell according to a further embodiment of the present invention may additionally incorporate a different conductive material (e.g., a conducting polymer) that serves to fill open porosity in the nanostructure (e.g., SWNT) network. The different conductive material may be mixed with nanostructures prior to deposition (e.g., to form a composite), and/or may be deposited separately (e.g., and allowed to diffuse into the nanostructure network).

The solar cell of the present invention may further comprise an electrode grid that is, for example, superimposed on the nanostructure network. This electrode grid may be composed of a conventional metal and/or may be at least semi-transparent (e.g., composed of nanostructures and/or ITO).

In an exemplary embodiment, the first electrode may be an anode comprising at least one network of nanostructures. The second electrode may also comprise a nanostructure network(s), but if it is to serve as a cathode a first buffer layer (e.g., a hole blocking layer with a low work function) may be required between the second electrode and the active layer. The solar cell may further comprise a second buffer layer (e.g., an electron blocking layer) between the first electrode and the active layer.

In a yet further embodiment, a solar cell according to the present invention may also comprise a second active layer sandwiched between a third electrode and the first or second electrode. Preferably, at least two of the first, second and third electrodes are at least semi-transparent to allow light transmission through to the multiple active layers. If the third electrode serves as a cathode, it may require a third buffer layer (e.g., a hole blocking layer with a low work function). In this way, transparent solar cells (e.g., thin-film solar cells) with different spectral responses may be stacked together with intervening at least semi-transparent electrodes (e.g., comprising nanostructure networks) to achieve high power conversion efficiency.

Other features and advantages of the invention will be apparent from the accompanying drawings and from the detailed description. One or more of the above-disclosed embodiments, in addition to certain alternatives, are provided in further detail below with reference to the attached figures. The invention is not limited to any particular embodiment disclosed.

### BRIEF DESCRIPTION OF THE DRAWINGS

The invention is better understood from reading the following detailed description of the preferred embodiments, with reference to the accompanying figures in which:

FIG. 1 is a schematic representation of solar cell according to an embodiment of the present invention.

FIG. 2 shows the sheet resistance versus transmittance for nanostructure-films produced according to an embodiment of the present invention.

FIG. 3 shows atomic force microscope (AFM) images of SWNT network films (a) before and (b) after PEDOT:PSS deposition and annealing.

FIG. 4 shows the current density-voltage characteristics of an organic solar cell according to an embodiment of the present invention under AM 1.5 G conditions.

FIG. 5 is a schematic representation of an optoelectronic device architecture according to an embodiment of the present invention, comprising a nanostructure-film, a electrode grid, and an active layer.

FIG. 6 is a schematic representation of an optoelectronic device architecture according to another embodiment of the present invention, comprising a conductive composite layer, an electrode grid, and an active layer.

FIG. 7 is a schematic representation of an optoelectronic device architecture according to yet another embodiment of the present invention, further comprising a conducting polymer layer within a multi-layer structure.

FIG. 8 graphs the optical transmission of a PEDOT binder-carbon nanotube network for light of given wavelengths.

FIG. 9 illustrates several nanostructure deposition methods that are compatible with embodiments of the present invention.

FIG. 10 is a flowchart outlining a fabrication method according to embodiments of the present invention.

FIG. 11 is a schematic representation of a multiple-active-layer solar cell device architecture according to an embodiment of the present invention, wherein both the anode and cathode comprise nanostructures.

FIG. 12 is a schematic representation of a multilayer solar cell device architecture according to another embodiment of the present invention, wherein the cathode comprises nanostructures.

FIG. 13 is a schematic representation of a multilayer solar cell device architecture according to yet another embodiment of the present invention, comprising stacked solar cell units, wherein both the anode(s) and cathode(s) comprise nanostructures.

FIG. 14 is a schematic representation of a multilayer solar cell device architecture according to yet another embodiment of the present invention, comprising stacked solar cell units, wherein the cathode(s) comprise nanostructures.

FIG. 15 shows the optical transmission of a nanostructure-film according to an embodiment of the present invention at infrared wavelengths.

Features, elements, and aspects of the invention that are referenced by the same numerals in different figures represent the same, equivalent, or similar features, elements, or aspects in accordance with one or more embodiments of the system.

### DETAILED DESCRIPTION OF THE PREFERRED EMBODIMENTS

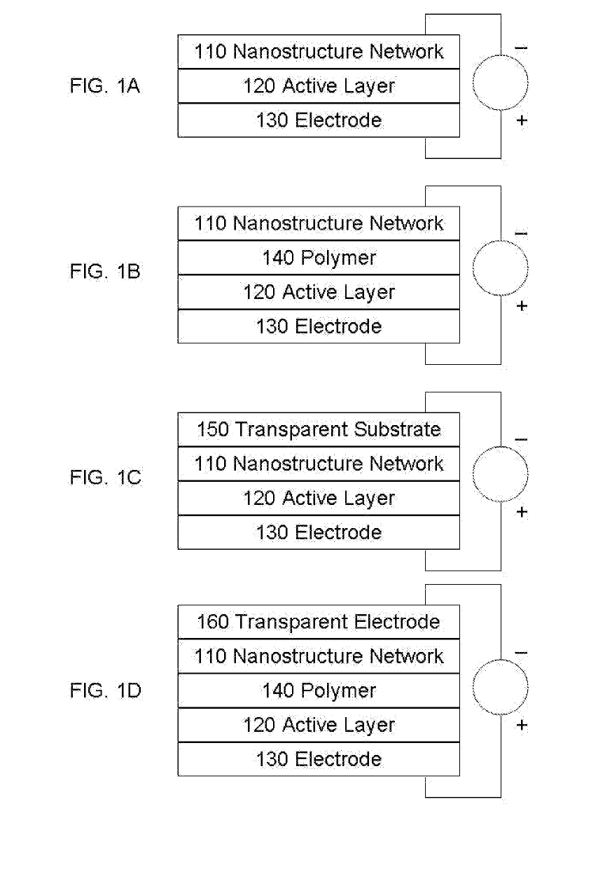

Referring to FIG. 1A, a solar cell according to an embodiment of the present invention comprises a nanostructure network 110, an active layer 120 and an electrode 130. A solar cell is a semiconductor device that converts photons from the sun (solar light) into electricity. Fundamentally, the device needs to photo-generate charge carriers (e.g., electrons and holes) in an active layer, and separate the charge carriers to a conductive electrode that will transmit the electricity.

The active layer 120 is preferably a strong light absorber such as, for example, one based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

The nanostructure network 110 may form a nanostructure-film, and may comprise, but is not limited to, nanotubes, nanowires, nanoparticles and/or graphene flakes. The nanostructure network 110 is preferably at least semi-transparent so as to allow light transmission through to the active layer(s), and electrically conductive so as to collect separated charges (e.g., holes) from the underlying active layer (e.g., as an anode). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

The electrode 130 is also preferably electrically conductive so as to collect separated charges (e.g., electrons) from the active layer (e.g., as a cathode). This electrode 130 may also be at least semi-transparent, but needs not be for many applications.

Referring to FIG. 1B, a solar cell according to another embodiment of the present invention further comprises a polymer 140, for example, between the active layer 120 and nanostructure network 110. This polymer is, preferably, electrically conductive so as to increase collection of separated charges, e.g., by filling in open porosity in the nanostructure network 110.

The polymer 140 may be deposited separately, and/or may be mixed with nanostructures and deposited as a composite layer. For example, SWNTs can be dispersed in aqueous solution and sonicated for a period of time, then mixed with an aqueous solution containing a conducting polymer. The mixture can then be sonicated and spin-coated onto a substrate, with the resulting film subsequently cured over a hotplate. Additionally or alternatively, a nanostructure network may be first deposited on a substrate, with a conducting polymer solution subsequently deposited onto the nanostructure network and allowed to freely diffuse.

In a preferred embodiment, the nanostructure network comprises SWNTs, and the conducting polymer comprises PEDOT:PSS. Other suitable conducting polymers may include, but are not limited to, ethylenedioxythiophene (EDOT), polyacetylene and poly(para phenylene vinylene) (PPV). The combination of different transparent and conducting layers can be used to optimize parameters such as the work function of the layer. The composite layer may additionally contain conducting nanoparticles to be used as resins for increasing the viscosity of nanostructure solutions.

In one experiment, a poly(3,4-ethylenedioxythiophene):poly(styrene sulfonate) (PEDOT:PSS) solution deposited onto a nanostructure network comprising single walled carbon nanotubes (SWNTs) reduced electrode sheet resistance by about 20% (e.g., to about 160 Ω/square). Given that the same PEDOT:PSS film (˜95 nm thick) spun on glass (i.e., with no nanostructures) had a sheet resistance of about 15 kΩ/square, the above drop in sheet resistance cannot be attributed merely to parallel conduction. Rather, the reduction in electrode sheet resistance may be attributed to a reduction in sheet resistance between conducting SWNTs (e.g., by filling a plurality of pores in the network) and/or doping of semiconducting SWNTs in the network.

Referring to FIGS. 1C and 1D, a solar cell according to additional embodiments of the present invention may further comprise a transparent substrate 150. The substrate 150 may be rigid or flexible, and may comprise, for example, glass, polyethylene terephthalate (PET), polyethylene naphthalate (PEN), polycarbonate (PC), polyethersulfone (PES) and/or Arton.

Nanostructure network(s) 110 may be deposited on the substrate 150 through a variety of techniques such as, for example, spraying, drop-casting, dip-coating and transfer printing, which are discussed in greater detail below.

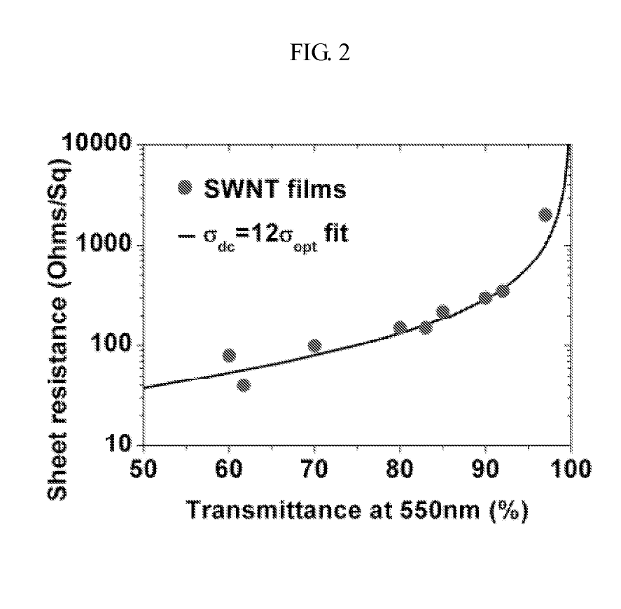

Referring to FIG. 2, a sheet resistance versus transmittance graph evidences the performance of a nanostructure-film produced according to an embodiment of the present invention, wherein the nanostructures are SWNTs. As in most materials, thicker films have a lower sheet resistance (i.e., higher electrical conductivity) and transmittance (i.e., less light can pass through a thicker material) than thinner films. Nanostructure film performance can be tailored to given device requirements by, for example, increasing or decreasing film thickness to attain desired transmittance and electrical conductivity.

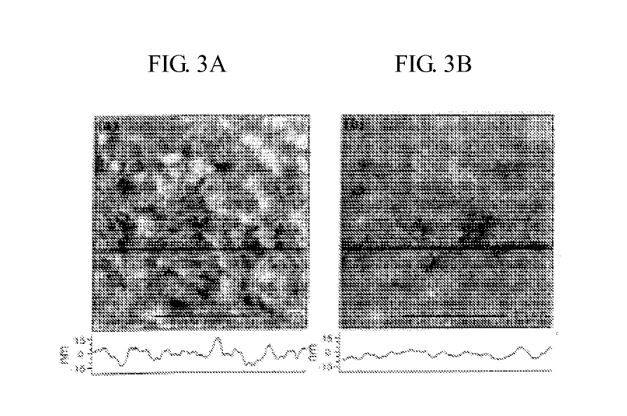

Referring to FIG. 3, atomic force microscope (AFM) images evidence nanostructure-films produced according to an embodiment of the present invention (a) before (see FIG. 3A) and (b) after (see FIG. 3B) PEDOT:PSS deposition and annealing. The nanostructure-films comprise SWNTs, and displayed substantial uniformity.

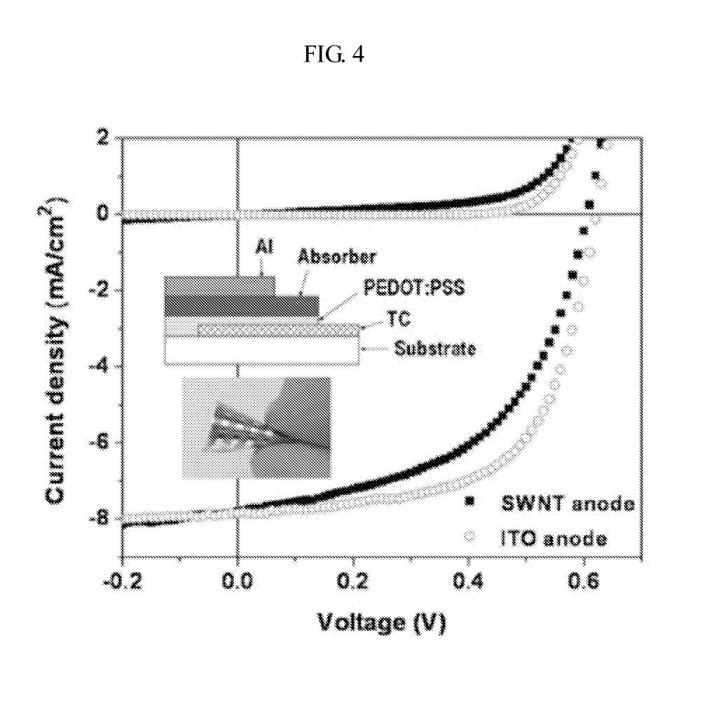

Referring to FIG. 4, a nanostructure-film electrode solar cell according to an embodiment of the present invention (e.g., using films similar to those imaged in FIG. 3) displayed performance comparable to more-conventional ITO electrode solar cells. In the tested embodiment, the organic active layer comprised P3HT:PCBM and the nanostructure-film electrode comprised a SWNT network(s) (e.g., on a flexible PET substrate) as an anode. Current density-voltage characteristics were plotted against another P3HT:PCBM device employing an ITO (e.g., on glass) anode. Under AM 1.5 G conditions, the devices fabricated using SWNT networks operated almost identically to those for ITO coated glass.

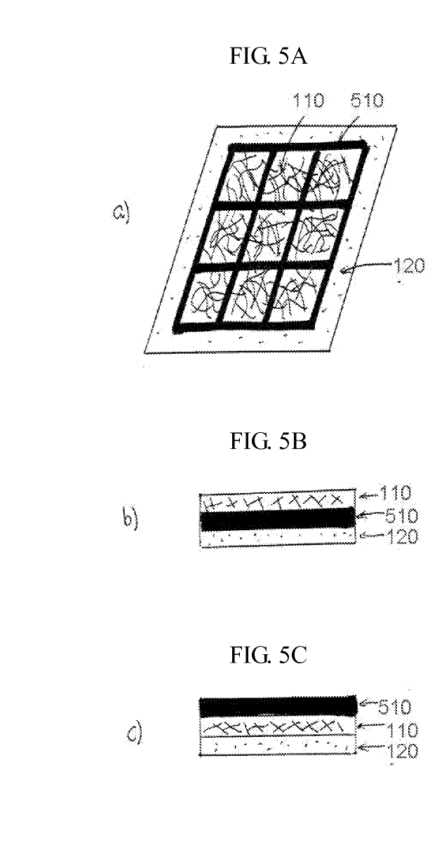

Referring to FIG. 5, a solar cell according to yet another embodiment of the present invention comprises an electrode grid 510, a nanostructure network 110, and an active layer 120. Patterned metal electrode grids are used in various applications, ranging from solar cells to touch screens and displays. These grids have good conductivity and can gather separated charges from an underlying active layer(s), but only if those charges can reach points on the functional layer(s) that contact the corresponding grid(s).

Unfortunately, such grids are generally not transparent and the electrodes thereof must typically be spaced relatively far apart to avoid unduly reducing light transmission to the underlying functional layer(s) (reduction is proportional to the fractional area covered by the metals). Consequently, devices (e.g., optoelectronics) in which charges are collected solely by a metal electrode grid(s) are usually quite inefficient, as many separated charges recombine before reaching an electrode.

A transparent conductor, such as a nanoscale network 110, that fills gaps in the metal electrode grid can improve device efficiency by allowing separated charges additional collection pathways. As depicted in FIGS. 5B and 5C, respectively, the nanostructure network 110 can be deposited either on top of or below the electrode grid. Additionally, as depicted in FIG. 5A, the nanostructure network 110 can be deposited between the electrodes of the electrode grid. The nanostructure network 110 will generally enhance device performance through its high work function, while the electrode grid 510 typically acts as the primary charge-harvesting element, to which charge and current flow from the nanostructure network 110.

The electrode grid may comprise a conventional metal, for example gold. Metal electrode grids can be fabricated using known processes such as standard lithographic techniques, shadow masking, and gold deposition techniques.

Additionally or alternatively, in a further embodiment of the present invention, the electrode grid is at least semi-transparent, comprising, for example, a patterned nanostructure network(s) and/or ITO.

### Example

### Solar Cell With Electrode Grid

In a solar cell, incoming light separates charges in a photosensitive active layer 120. However, these separated charges usually cannot travel far within this usually-thin functional layer before recombining.

Electrodes in an electrode grid 510 can gather these separated charges, but only if the charges can reach points in the active layer 120 that contact the electrodes 510. Unfortunately, these electrodes 510 must be spaced relatively far apart in a conventional metal electrode grid, given that the non-transparent electrodes thereof reduce light transmission to the underlying active layer 120 (the reduction in light transmission is proportional to the fractional area covered by the non-transparent electrodes of the metal electrode grid 510). Semi-transparent electrodes can be more closely spaced, however without an additional transparent conductive layer(s), a solar cell having only an electrode grid may nonetheless have low efficiency.

Solar cell efficiency can be increased markedly by employing a nanostructure network(s) 110 as a transparent conductor, in accordance with an embodiment of the present invention. Whether above, below, or deposited within an electrode grid, the nanostructure network 110 provides additional pathways for separated charges to more easily and successfully reach the electrodes of the electrode grid 510.

In an exemplary embodiment, both the nanostructure network 110 and the electrode grid 510 comprise nanostructures, given that a thick nanostructure network can have both metallic properties and low sheet resistance. For example, a device according to the present invention may comprise a thin SWNT network superimposed on a thick SWNT network, wherein the latter network acts as an electrode grid.

Various methods for fabricating and depositing nanostructure networks are described in PCT application US/2005/047315 “Components and Devices Formed Using Nanoscale Materials and Methods of Production.”

Similarly, there are a variety of methods for fabricating electrode grids. For example, a patterned SWNT film can be fabricated using standard lithographic techniques. The new electrode architecture can be made by, for example, either depositing nanostructure films on the grid or depositing the grid on nanostructure films.

In an additional embodiment of the present invention, a nanostructure network solar cell fabricated according to the method described by M. Rowell, et al., Appl. Phys. Lett 88, 233506 (2006) can be improved by incorporating the electrode architecture of the present invention.

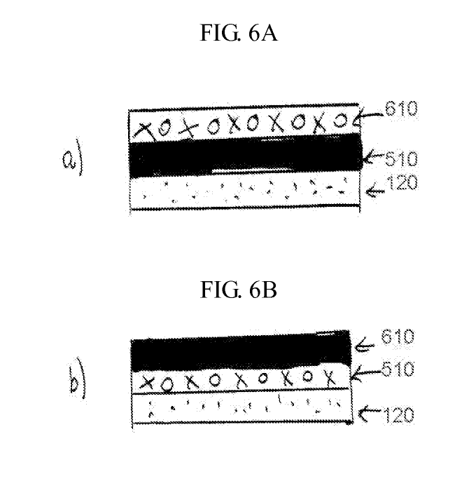

Referring to FIGS. 6A and 5B, a further embodiment of the invention is an architecture comprising an electrode grid 510 and a composite layer 610. The composite layer 610 may comprise a nanostructure network and at least one additional conducting material. For example, the composite layer 610 may be a SWNT network and a conducting polymer, wherein the conducting polymer serves as a binder for the nanostructure network. Such nanostructure networks have shown very robust mechanical and electrical properties, as described above.

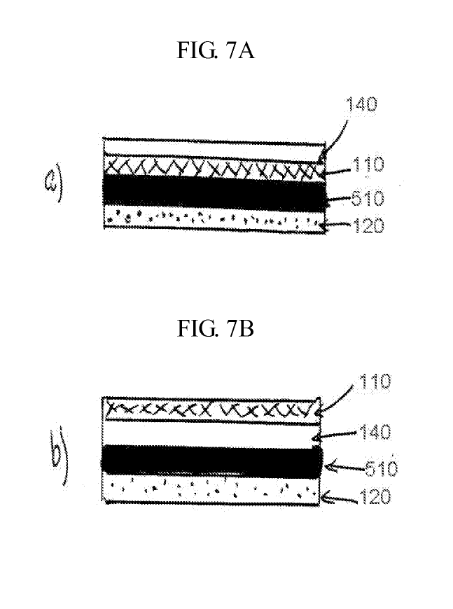

Referring to FIGS. 7A and 7B, the nanostructure network 110 and different conductive material can also or alternatively form a multi-layer structure. The different conductive material may be a conducting polymer (e.g., PEDOT:PSS) forming a distinct layer 140 on top of or beneath the nanostructure network 110, while preferably filling a plurality of pores in the nanostructure network 110.

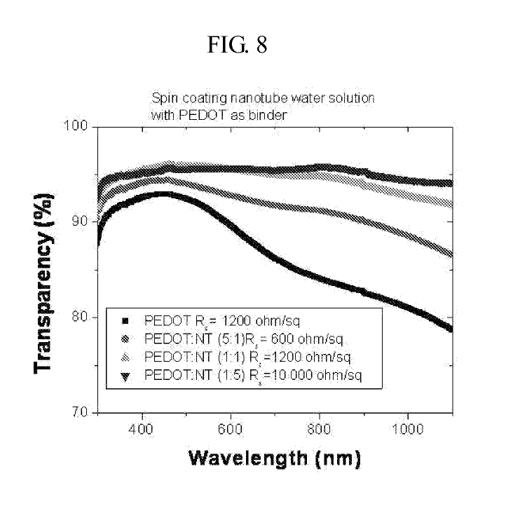

Referring to FIG. 8, an optical transmission graph of a PEDOT binder-SWNT network demonstrates the viability of the nanostructure networks of the present invention for optoelectronic applications.

To fabricate this exemplary sample, water soluable arc-discharged nanotube powder from Carbon Solutions Inc. was first dispersed in distilled oxide (DI) water by bath sonication with 100 W for 2 hours. Nanotube solution and PEDOT:PSS (Baytron F. HC) in water were then mixed together in different proportions. The resulting mixture was subsequently bath-sonicated for 1 hour.

The solution was spin-coated onto a pre-cleaned glass slide at a speed of 1000 rpm, and cured over a hotplate at 120 degrees for 18 minutes. The transmittance and sheet resistance of the films was measured and plotted in FIG. 8.

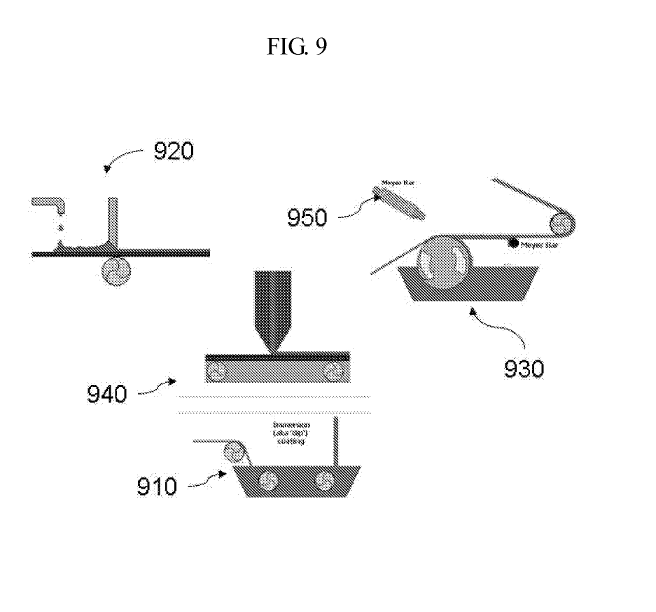

Referring to FIG. 9, in addition to spin-coating with a conductive polymer binder, a nanostructure solution/film may be deposited onto a substrate using a number of different methods. Such methods include, but are not limited to, spray coating, dip coating 910, drop coating 920 or casting, roll coating 930 and/or inkjet printing 940. A Meyer rod 950 may be used to squeeze the solutions for a more uniform nanostructure solution coating.

Additionally or alternatively, nanostructures may be deposited using a transfer stamping method. For example, commercially available SWNTs (e.g., produced by arc discharge) may be dissolved in solution with surfactants and then sonicated. The well dispersed and stable solutions may then be vacuum filtered over a porous alumina membrane. Following drying, the SWNT films may be lifted off with a poly(dimethylsiloxane) (PDMS) stamp and transferred to a flexible poly(ethylene terephthalate) (PET) substrate by printing.

This method has the added advantage of allowing deposition of patterned films (e.g., where the PDMS stamp is already patterned). Other compatible patterning methods include, but are not limited to, photolithography/etching and liftoff (e.g., using photoresist or toner).

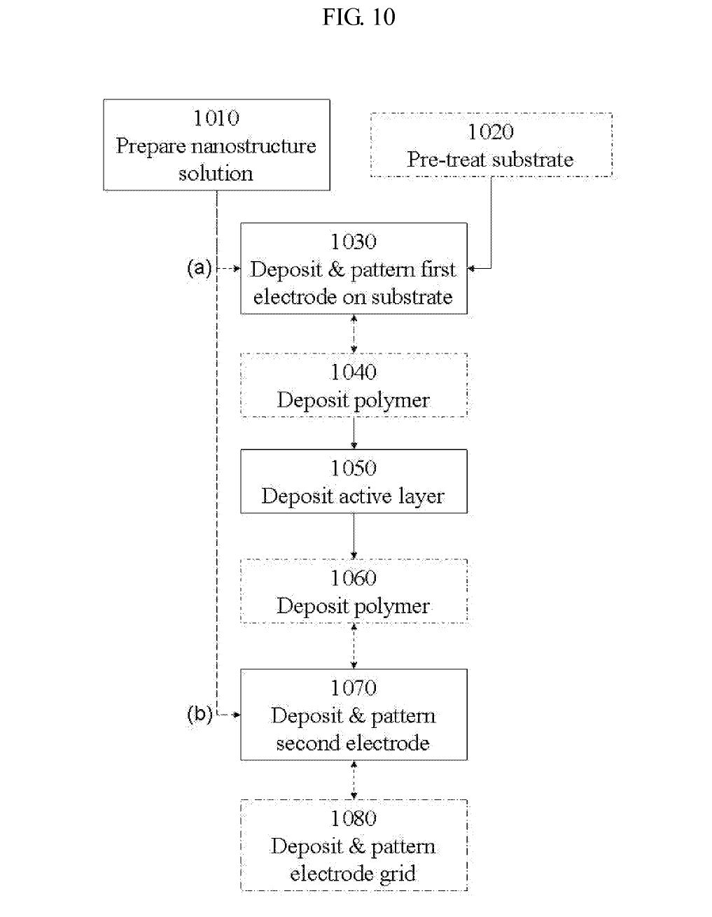

Referring to FIG. 10, a method for fabricating solar cells according to above-described and other embodiments of the present invention is provided. This method comprises preparing a nanostructure solution 1010 and pre-treating a substrate 1020. The latter step may be omitted depending on the types of substrates and surfactants used. For example, transparent substrates such as PET, PEN, polycarbonate, or glass do not generally require pretreatment if Triton-X is used as a surfactant.

In an exemplary embodiment of the present invention, the nanostructure solution may be prepared by dispersing water soluble arc-discharged nanotube powder from Carbon Solutions Inc. in distilled oxide (DI) water by bath sonication with 100 W for 2 hours. This solution may further be mixed with a different conductive material (e.g., a conductive polymer binder such as PEDOT:PSS) at this stage to form a composite.

The solar cell begins to take shape when the first electrode is deposited and patterned (patterning is optional), for example, on the substrate 1030. The nanostructure-film may be patterned before (e.g., using PDMS stamp transfer), during (e.g., using a lift-off technique) or after (e.g., using photolithography and etching) deposition. The substrate is preferably transparent, but does not need to be for all embodiments and/or applications. The first electrode may be an anode or a cathode, depending, for example, on whether an electrode grid is to be included in the device.

In a first embodiment, wherein the device comprises a single active layer and no electrode grid, the first electrode is an anode comprising a nanostructure network. The nanostructures comprising the network are preferably SWNTs (prepared in step 1010 following (a)), which may be deposited by such methods as those described in connection with FIG. 9.

For example, the substrate may be dipped into the nanostructure solution, the former having been either treated or matched with an appropriate surfactant such that a layer of solution coats the substrate surface. The solvent may then be evaporated from the solution, preferably in a uniform manner using, for example, a flash-drying method (where evaporation begins on one side of the substrate, and sweeps across the substrate in a “drying wave”). Heat can be applied in various manners, e.g., by linear heating bar or infrared laser. Additionally, solvent evaporation may be aided by air-flow blow drying.

Where a surfactant is used, the substrate will preferably undergo a subsequent wash to remove surfactant from the dried nanostructure-film on the substrate. Washing may comprise rinsing the film with water, and then drying it with air-flow blow dry or heat. Other rinsing agents can be used, e.g., methanol.

Additionally or alternatively, the first electrode may comprise a composite material of nanostructures and, for example, a conductive polymer binder. Such composites may be sonicated and spin-coated onto a substrate, with the resulting film subsequently cured over a hotplate.

Additionally or alternatively, the first electrode may comprise a composite material of nanostructures and, for example, a conductive polymer binder. Such composites may be sonicated and spin-coated onto a substrate, with the resulting film subsequently cured over a hotplate.

In another example, a nanostructure network is first deposited on a substrate 730, and a conducting polymer solution is then deposited 740 onto the nanostructure network and allowed to freely diffuse. Alternatively, the polymer may be deposited 1040 before the nanostructure network 1030. Preferably, even where the different conducting material is deposited separately, it will fill a plurality of pores in the adjacent nanostructure network.

For example, in one experiment, a 30-nm-thick SWNT network film (T=85%, Rs=200 Ω/square) deposited on a poly(ethylene terephthalate) (PET) flexible substrate was coated with a PEDOT:PSS by spin-casting (e.g., at 1000 rpm) and then heating the substrate (e.g., on a 110° C. hotplate for 20 minutes). Consistent results were obtained when either the PEDOT:PSS solution was applied on the surface and let free to diffuse several minutes before the spin-coating operation in order to fill in open porosity of the SWNT film or when a PEDOT:PSS/isopropanol 1:1 mix was used to improve the wetting.

Once the first electrode 1030 and optional different conducting material 1040 are deposited on the substrate, an active layer may be deposited onto the first electrode and/or different conducting material. Preferably, the active layer is photosensitive and may be based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials.

In an exemplary embodiment, an organic active layer is deposited by transferring a PET substrate coated with a 30-nm-thick SWNT film and a PEDOT:PSS layer with low roughness to an inert glove box where a solution of MDMO-PPV/PCBM in a 1:4 weight ratio or P3HT/PCBM in a 1:0:8 weight ratio (10 mg P3HT/mL) in chlorobenzene was spin-cast at 700 rpm.

In another exemplary embodiment, thin silicon active layers are deposited on a transparent substrate (e.g., glass) by chemical vapor deposition (CVD). For example, amorphous silicon may be deposited using hot-wire chemical vapor deposition (CVD) (e.g., decomposing silane gas (SiH4) using a radiofrequency discharge in a vacuum chamber) or alternatively may sputter deposited (e.g., using ZnO/Ag). Nanocrystalline silicon may also be deposited effectively by hot-wire CVD (e.g., using a high hydrogen dilution (H2/SiH4=166), a high gas pressure of 2 Torr, and a high power-density of 1.0 W/cm2 at a low substrate temperature of 70° C.). Similarly, protocrystalline silicon may be deposited using photo-assisted CVD (e.g., employing alternate H2 dilution under continuous ultraviolet (UV) light irradiation).

In yet another exemplary embodiment, a cadmium telluride active layer (CdTe) is deposited, possibly with a corresponding cadmium sulphide (CdS) layer, using close-space sublimation (CSS) (e.g., based on the reversible dissociation of the materials at high temperatures: 2CdTe(s)=Cd(g)+Te2(g)). Alternatively, physical vapour deposition (PVD), CVD, chemical bath deposition and/or electrodeposition may be used.

In still another exemplary embodiment, copper-indium-gallium-selinide (CIGS) may be deposited using a rapid thermal annealing and anodic bonding process. Thermal annealing processes are also compatible with copper-indium-selinide (CIS) systems, the parent systems for CIGS.

In additional exemplary embodiments, gallium arsenide (GaAs) solar cells may be fabricated from epilayers grown directly on silicon substrates by atmospheric-pressure Metal Organic chemical vapor deposition (MOCVD); and active layers comprising quantum dots, (e.g., suspended in a supporting matrix of conductive polymer or mesoporous metal oxide) may be fabricated by growing nanometer-sized semiconductor materials on various substrates (e.g., using beam epitaxy on a semi-insulating GaAs(100) substrate).

After the active layer is deposited, another optional conductive material may be deposited 1060. Preferably, this material is deposited when the second electrode comprises a nanostructure network.

Finally, a second electrode may be deposited 1070 to complete the basic device architecture. In said first embodiment, this second electrode (e.g., cathode) needs not be transparent, and thus may comprise a conventional metal (e.g., Aluminum) deposited using known techniques. Alternatively, in later-described embodiments, this second electrode is preferably at least semi-transparent (e.g., comprising a nanostructure network(s) and/or ITO).

In a second embodiment of the present invention, a solar cell again comprises a single active layer, but this time further comprises an electrode grid for increased performance.

In this embodiment, steps 1010 and 1020 remain the same, however the first electrode deposited in step 1030 may be, for example, a non-transparent cathode. Accordingly, the second electrode deposited and patterned in step 1070 is preferably at least semi-transparent and comprises a network of nanostructures.

The electrode grid may be deposited 1080 before, after or concurrently with the second electrode and/or optional other conducting material (e.g., polymer). The electrode grid is preferably at least semi-transparent, and may, for example, comprise nanostructures and/or ITO. For example, a thin network of SWNTs can be deposited on the functional layer, with a thick SWNT grid subsequently deposited and patterned on top using a lithography mask. Preferably, whether deposited before, after or concurrently, the network of nanostructures will fill gaps in the electrode grid (e.g. see FIG. 5(a)).

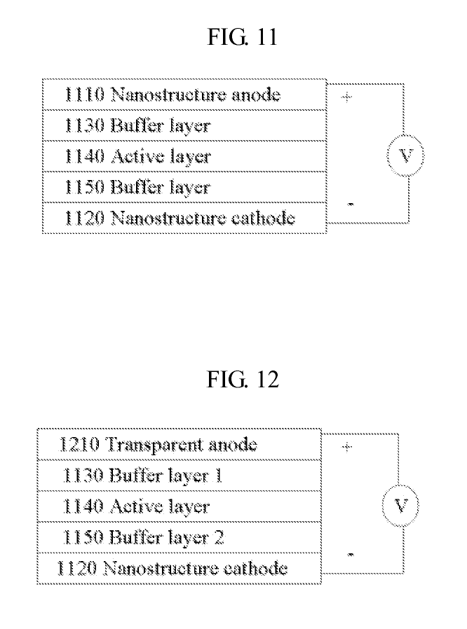

Referring to FIG. 11, a third embodiment of the present invention comprises multiple active layers and at least one pair of semi-transparent anode(s) and cathode(s). Thin-film solar cells with, for example, polymer and/or nanostructure active layers provide promising cost effective alternatives to silicon-based solar cells. Unfortunately, while the external quantum efficiency of such solar cells is approaching that of their inorganic semiconductor counterparts, limited absorption in solar spectrum remains a major limitation to achieve high power conversion efficiency.

To solve this problem, it is widely accepted that multiple solar cells in tandem, covering different spectral regions, must be used. However, it is difficult to realize multiple polymer films in tandem without destroying the underlying polymer layer(s). An alternative approach is to fabricate efficient transparent solar cells (e.g., polymer solar cells) with different spectral responses and stack them together with intervening at least semi-transparent electrodes (that allow light transmission through to underlying active layers).

Nanostructure-films, such as those comprising SWNTs, are typically good transparent electrical conductors with high work functions, making them well-suited for use as an anode 1110. Such films can be used as a cathode 1120 with, for example, the addition of a low work function buffer layer 1150 (e.g., a hole-blocking layer such as copper phthalocyanine (CuPc), cesium carbonate (Cs2CO3) and/or titanium dioxide (TiO₂)) between the cathode 1120 on one side, and the active layer 1140 and anode 1110 on the other. Preferably, another buffer layer 1130 (e.g., an electron-blocking layer such as PEDOT:PSS) is included for optimal device efficiency. These buffer layers are preferably at least semi-transparent.

Referring to FIG. 12, a nanotube cathode 1120 may be incorporated into a solar cell according to an embodiment of the present invention regardless of the composition of the anode 1210, so long as the anode is electrically conductive with an appropriate work function.

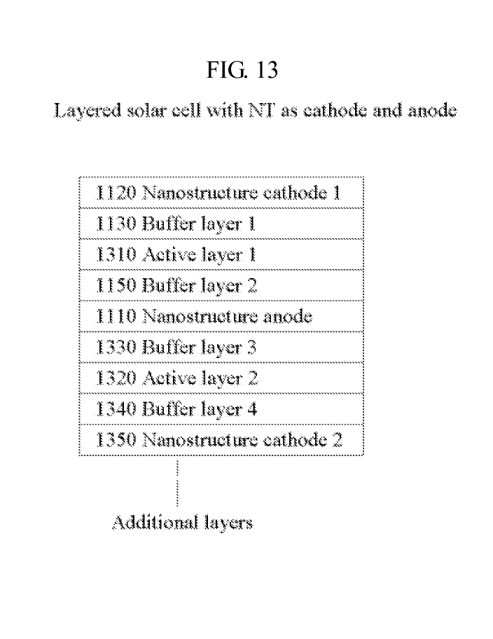

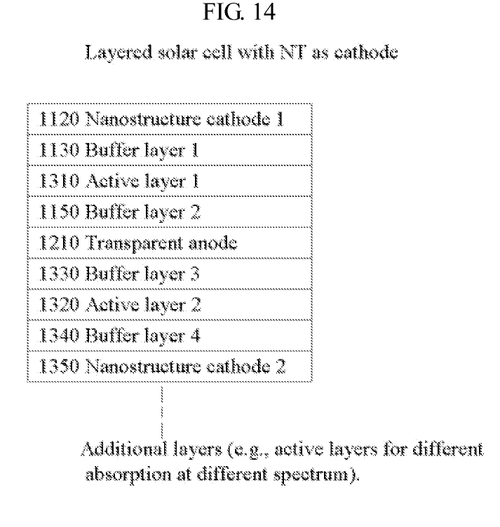

Referring to FIG. 13, the above-described devices are stackable, such that multiple active layers with different spectral responses can extract as much energy as possible from incoming light. Because certain electrodes are at least semi-transparent, light can pass through nanostructure cathode 1 1120 to active layer 1 1310, separating charges (e.g., holes and electrons) that are collected by cathode 1 1120 and anode 1110, and then pass through anode 1110 to active layer 2 1320, separating charges that are collected by anode 1110 and cathode 2 1350. Different buffer layers may be required based on the work functions of the respective active layers and electrodes.

Referring to FIG. 14, the cathodes may comprise nanostructures regardless of the composition of the anode(s) 1210 in a multiple-active-layer device as well, again so long as the anode(s) is electrically conductive.

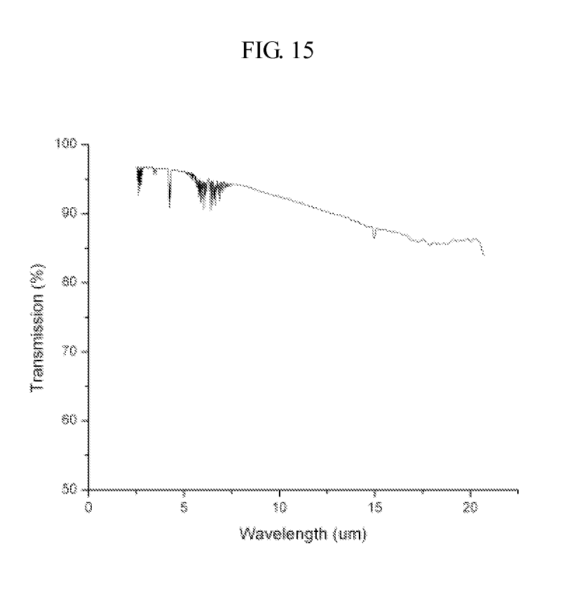

Referring to FIG. 15, multiple-active-layer solar cells according to embodiments of the present invention may further expand solar cell capabilities by allowing the conversion of infrared-wavelength light. Unlike ITO, many nanostructure-films (e.g., those comprising SWNT network(s)) allow substantial transmission of infrared wavelength light. Accordingly, when combined with an appropriate active layer, electrode(s) comprising such films can harness this traditionally-untapped energy. Likewise, single-active-layer solar cells according to the present invention may be designed to convert solar energy from the infrared spectrum.

The present invention has been described above with reference to preferred features and embodiments. Those skilled in the art will recognize, however, that changes and modifications may be made in these preferred embodiments without departing from the scope of the present invention. These and various other adaptations and combinations of the embodiments disclosed are within the scope of the invention.

1-20. (canceled)

21. An optoelectronic device, comprising:
an optoelectronic active layer;
a first electrode; and
a second electrode, wherein one of the first and second electrodes is a cathode comprising at least one first network of nanostructures,
wherein at least one of the first and second electrodes is transparent, and
wherein the optoelectronic active layer is located between the first and second electrodes.

22. The optoelectronic device of claim 21, wherein the nanostructures are nanotubes.

23. The optoelectronic device of claim 22, further comprising a polymer coating on the network of nanostructures, wherein the polymer coating fills a plurality of pores in the network of nanostructures.

24. The optoelectronic device of claim 23, further comprising a first buffer layer between the cathode and the optoelectronic active layer.

25. The optoelectronic device of claim 24, wherein both the first and second electrodes are transparent.

26. The optoelectronic device of claim 25, wherein one of the first and second electrodes is an anode comprising at least one second network of nano structures.

27. The optoelectronic device of claim 26, further comprising a second buffer layer between the anode and the optoelectronic active layer.

28. The optoelectronic device of claim 27, wherein the active layer comprises a photosensitive material that produces electricity when exposed to light.

29. The optoelectronic device of claim 28, wherein the photosensitive material comprises one of a group consisting of amorphous silicon, protocrystalline silicon, nanocrystalline silicon, cadmium telluride (CdTe), copper indium gallium selenide (CIGS), copper indium selenide (CIS), gallium arsenide (GaAs), light absorbing dyes, quantum dots and organic semiconductors.

30. The optoelectronic device of claim 29, further comprising:
a second active layer; and
a third electrode, wherein the second active layer is located between the third electrode and one of the first and second electrodes, and
wherein at least two of the first, second and third electrodes are transparent.

31. The optoelectronic device of claim 27, wherein the active layer comprises an emissive electroluminescent material.

32. The optoelectronic device of claim 31, wherein the emissive electroluminescent material comprises an organic semiconductor.

33. The optoelectronic device of claim 21, further comprising an electrode grid, wherein the electrode grid is superimposed on the network of nano structures.

34. The optoelectronic device of claim 21, wherein the electrode grid is at least semi-transparent.

35. The optoelectronic device of claim 21, wherein the network of nanostructures has a sheet resistance of less than 300 Ω/square and at least 90% optical transmission of 550 nm light.

36. A method of fabricating an optoelectronic device, comprising:
depositing a first electrode on a substrate;
depositing a first buffer layer on the first network of nanostructures;
depositing an first active layer on the first buffer layer;
depositing a second buffer layer on the active layer; and
depositing a second electrode on the second buffer layer, wherein at least one of the first and second electrodes is transparent, and
wherein at least one of the first and second electrodes is a cathode comprising a network of nanostructures.

37. The method of claim 36, wherein both the first and second electrodes are transparent.

38. The method of claim 37, further comprising:
depositing a third buffer layer on one of the first electrode and the second electrode; and
depositing a second active layer on the third buffer layer.

39. A solar cell, comprising:
an active layer;
a first electrode; and
a second electrode, wherein the first electrode is a cathode comprising at least one first network of nanotubes,
wherein the first electrodes is transparent, and
wherein the active layer is located between the first and second electrodes.

40. The solar cell of claim 39, wherein the second electrode is an anode comprising a second network of nanotubes.
